(19) United States
(12) Patent Application Publication
(10) Pub. No.: US 2007/0187711 A1
(43) Pub. Date: Aug. 16, 2007

(54) Wafer level package for image sensor components and fabricating method thereof

(75) Inventors: Wei-Min Hsiao, Kaohsiung (TW); Kuo-Pin Yang, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/647,408

(22) Filed: Dec. 29, 2006

(30) Foreign Application Priority Data
Jan. 11, 2006 (TW) 95100993

(51) Int. Cl. H01L 33/00

(52) U.S. Cl. 257/100

(57) ABSTRACT

A wafer level package for image sensor components includes an image sensor chip and several metal pillars. Several vias formed in the image sensor chip are aligned with several bonding pads. The metal pillars are formed in the vias. First ends of the metal pillars are bonded to the bonding pads. Second ends of the metal pillars protrude from a back surface of the image sensor chip. The length of the metal pillars is greater than the thickness of the image sensor chip. The image sensor chip is mounted to a printed circuit board through the metal pillars formed in the vias instead of wire bonding or redistribution line (RDL) process. There is no need to dispensing underfil between the image sensor chip and the printed circuit board to protect the metal pillars.

This application claims the benefit of Taiwan application Serial No. 95100993, filed Jan. 11, 2006, the subject matter of which is incorporated herein by reference.

### BACKGROUND OF THE INVENTION

1. Field of the Invention

The invention relates in general to a package for image sensor components, and more particularly to a wafer level package for image sensor components.

2. Description of the Related Art

For meeting the demand for multifunction and light weight electronic products, semiconductor packages are evolved into wafer level chip scale packages (WLCSP). Wafer level chip scale packages have not only smaller volume but also better capacity. Solder balls are reflowed to be bonded to a substrate in a conventional wafer level package for image sensor components. Underfill is dispensed when necessary between the substrate and the package to protect the solder balls from breaking due to the stress.

Please referring to FIG. 1, a conventional wafer level package 100 for image sensor components is illustrated in FIG. 1. The conventional wafer level package 100 includes an image sensor chip 110, a first adhesive layer 120 and a second adhesive layer 130. The image sensor chip 110 has an active surface 111, a back surface 112 and several side surfaces 113. A sensor area 114 and several bonding pads 115 are formed on the active surface 111. A protective layer 140 is formed on the active surface 111 and exposes the bonding pads 115. Afirst circuit layer 150 is formed on the protective layer 140 and electrically connected to the bonding pads 115. The first adhesive layer 120 covers the first circuit layer 150 and the protective layer 140. The first adhesive layer 120 is transparent and preferably formed by press molding or printing. The second adhesive layer 130 is formed on the back surface 112 of the image sensor chip 110. Several contact pads 160 are formed on the second adhesive layer 130. Asecond circuit layer 170 is formed on the side surfaces 113 of the image sensor chip 110 and the second adhesive layer 130. The second circuit layer 170 is electrically connected to the first circuit layer 150 and the contact pads 160. The bonding pads 115 are electrically connected to the contact pads 160 through the first circuit layer 150 and the second circuit layer 170. A solder-mask layer 180 is formed on the second circuit layer 170 to protect the second circuit layer 170. Several solder balls 190 are formed on the contact pads 160. However, after the solder balls 190 are reflowed to be bonded to a substrate (not shown in FIG. 1), underfill is dispensed between the substrate and the contact pads 160 to protect the solder balls 190.

### SUMMARY OF THE INVENTION

The invention is directed to a wafer level package for image sensor components and a fabricating method thereof. Several vias of the an image sensor chip are aligned with bonding pads, so that several metal pillars formed in the vias are bonded to the bonding pads. The image sensor chip is mounted to a printed circuit board through the metal pillars instead of die attaching or redistribution line (RDL) process. There is no need to redistribute circuits on the surface of the image sensor chip. Furthermore, there is no need to dispense underfill between the image sensor chip and the printed circuit board to protect the metal pillars.

According to the present invention, a wafer level package for image sensor components is provided. The package includes an image sensor chip and several metal pillars. The image sensor chip has an active surface, a back surface and several vias. The active surface includes an image sensor area and several bonding pads. The vias are aligned with the bonding pads. The metal pillars are formed in the vias. The length of the metal pillars is greater than the thickness of the image sensor chip. First ends of the metal pillars are bonded to the bonding pads. Second ends of the metal pillars protrude from the back surface of the image sensor chip.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view of a conventional wafer level package for image sensor components;

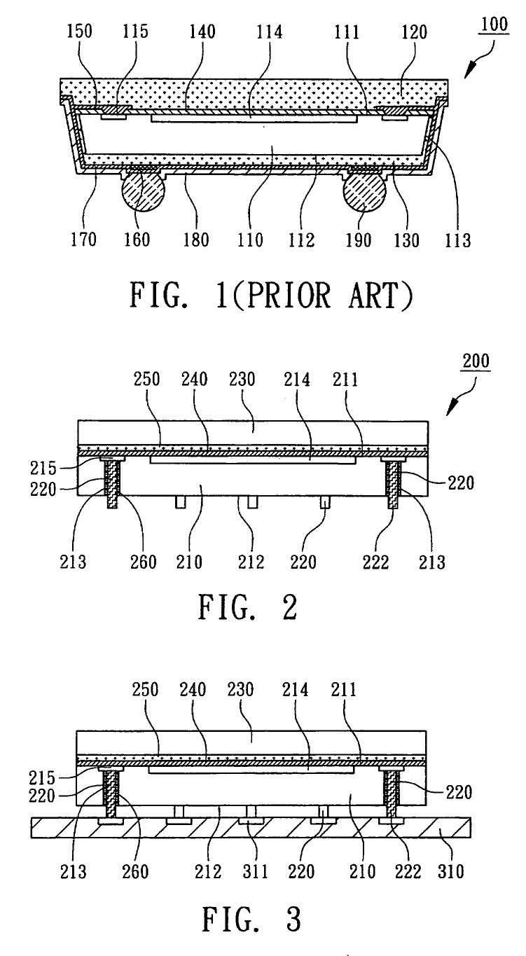

FIG. 2 is a cross-sectional view of a wafer level package for image sensor components according to a preferred embodiment of the invention;

FIG. 3 is a cross-sectional view of the wafer level package mounted on a printed circuit board according to the preferred embodiment of the invention; and

FIGS. 4A˜4H are cross-sectional views of a fabricating method of the wafer level package for image sensor components according to the preferred embodiment of the invention.

### DETAILED DESCRIPTION OF THE INVENTION

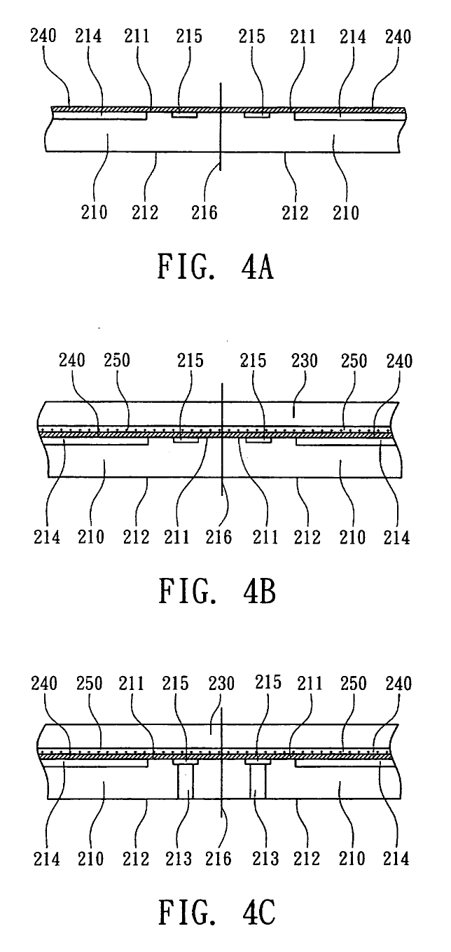

Please referring to FIG. 2, a wafer level package 200 for image sensor components according to a preferred embodiment of the invention is illustrated in FIG. 2. The wafer level package 200 includes an image sensor chip 210 and several metal pillars 220. The image sensor chip 210 has an active surface 211, a back surface 212 and several vias 213. The active surface 211 includes an image sensor area 214 and several bonding pads 215. A protective layer 240 made of transparent material is formed on the active surface 211. Furthermore, a glass sheet 230 is disposed on the active surface 211. An epoxy resin 250 made of transparent material is disposed on the active surface 211 to protect the image sensor area 214. The vias 213 are formed in the image sensor chip 210 and surrounding the image sensor area 214 on the active surface 211. Insulation layers 260 are preferably formed on inner walls of the vias 213 to protect the image sensor chip 210 form short circuit. The insulation layers 260 are made of silicon dioxide (SiO₂) for example. The vias 213 are aligned with the bonding pads 215. Preferably, the area of the bonding pads 215 is greater than that of the vias 213, so that the metal pillars 220 are bonded to the bonding pads 215 easily. The metal pillars 220 are formed in the vias 213 and preferably made of single metal. For example, the metal pillars 220 are made of electroplated copper. First ends 221 of the metal pillars 220 are bonded to the bonding pads 215. Second ends 222 of the metal pillars 220 protrude from the back surface 212 of the image sensor chip 210. The length of the second ends 222 of the metal pillars 220 protruding from the back surface 212 is between 5 μm and 10 μm. The length of the metal pillars 220 is greater than that of the image sensor chip 210.

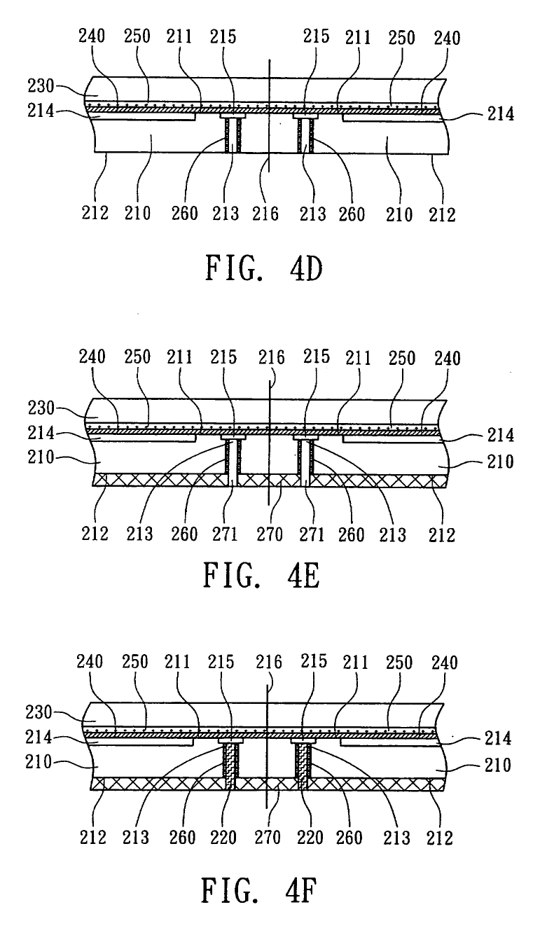

As shown in FIG. 3, the metal pillars 220 are bonded on several contact pads 311 of a printed circuit board 310 by surface mount technology (SMT) for electrically connecting the image sensor chip 210 and the printed circuit board 310. Conventional die attaching and wire bonding process of the image sensor components are replaced by the surface mount technology. Therefore, there is no need to redistribute circuits on the surface of the image sensor chip and to dispense the underfill.

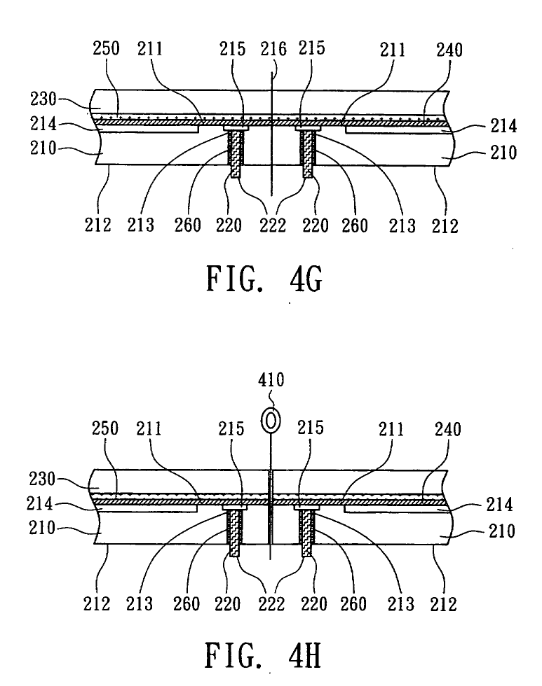

A fabricating method of the wafer level package 200 for image sensor components is illustrated in FIGS. 4A˜4H. First, at least an image sensor chip 210 is provided as shown in FIG. 4A. The image sensor chip 210 is formed in a semiconductor wafer. The semiconductor wafer includes the image sensor chip 210 and several cutting streets 216. The image sensor chip 210 has an active surface 211 and a back surface 212. A protective layer 240 is formed on the active surface 211 and between an epoxy resin 250 and the active surface 211 to protect an image sensor area 214 on the active surface 211. Several bonding pad 215 are formed on the active surface 211. Next, as shown in FIG. 4B, the epoxy resin 250 is formed on the protective layer 240 of the active surface 211 to fix a glass sheet 230 on the active surface 211. The glass sheet 230 is used for protecting the image sensor area 214. Then, as shown in FIG. 4C, several vias 213 are formed in the image sensor chip 210 by etching or laser drilling. The vias 213 are aligned with the bonding pads 215. In the present embodiment, the area of the bonding pads 215 is greater than that of the vias 213. Afterwards, as shown in FIG. 4D, insulation layers 260 are preferably formed on the inner walls of the vias 213 to protect the image sensor chip 210 for short circuit. The insulation layers 260 are made of silicon dioxide (SiO₂) for example. The insulation layers 260 preferably extend to the back surface 212 (not shown in FIGS) of the image sensor chip 210. Subsequently, as shown in FIG. 4E, a photoresist layer 270 is preferably on the back surface 212 of the image sensor chip 210 by spin coating or dry film attaching. The thickness of the photoresist layer 270 is substantially between 5 μm and 10 μm. Several holes 271 are formed in the photoresist layer 270 by exposure and development. The holes 271 are aligned with the vias 213. Later, as shown in FIG. 4F, several metal pillars 220 are formed in the vias 213 and the holes 271 by filling or electroplating. Thereon, as shown in FIG. 4G, the photoresist layer 270 is removed. First ends 221 of the metal pillars 220 are bonded to the bonding pads 215. Second ends 222 of the metal pillars 220 protrude from the back surface 212. The length of the second ends 222 protruding from the back surface 212 is preferably determined by the thickness of the photoresist layer 270. In the present embodiment, the length of the second ends 222 protruding from the back surface 212 is substantially between 5 μm and 10 μm. Then, as shown in FIG. 4H, the wafer is cut along the cutting streets 216 by a cutter 410 to form the wafer level package 200 for image sensor components in FIG. 2.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A wafer level package for image sensor components, the package comprising:
an image sensor chip having an active surface, a back surface and a plurality of vias, the active surface comprising an image sensor area and a plurality of bonding pads, the vias aligned with the bonding pads; and
a plurality of metal pillars formed in the vias, first ends of the metal pillars bonded to the bonding pads, second ends of the metal pillars protruding from the back surface of the image sensor chip, and the length of the metal pillars being greater than the thickness of the image sensor chip.

2. The package according to claim 1 further comprising a glass sheet disposed on the active surface.

3. The package according to claim 2, further comprising a transparent epoxy resin formed on the active surface to fix the glass sheet on the active surface.

4. The package according to claim 3, further comprising a transparent protective layer formed between the epoxy resin and the active surface to protect the image sensor area on the active surface.

5. The package according to claim 2, further comprising a transparent protective layer formed on the active surface to protect the image sensor area on the active surface.

6. The package according to claim 5, further comprising a transparent epoxy resin formed on the protective layer of the active surface to fix the glass sheet thereon.

7. The package according to claim 1, wherein the metal pillars are electroplated copper

8. The package according to claim 1, further comprising insulation layers formed on inner walls of the vias.

9. The package according to claim 1, wherein the length of the second ends protruding from the back surface is substantially between 5 μm and 10 μm.

10. The package according to claim 1, wherein the vias are formed in the image sensor chip and surrounding the image sensor area on the active surface.

11. The package according to claim 1, wherein the area of the bonding pads are greater than the area of the openings of the vias.

12. The package according to claim 1, wherein the metal pillars are made of single metal.
